(19) United States
(12) Patent Application Publication
(10) Pub. No.: US 2002/0062783 A1
(43) Pub. Date: May 30, 2002

(54) Method and device for controlling crystal growth

(76) Inventor: Terry Lee Bray, Birmingham, AL (US)

Correspondence Address: Barnes & Thornburg, 11 South Meridian Street, Indianapolis, IN, 46204, US

(21) Appl. No.: 09/853,467

(22) Filed: May 11, 2001

Related U.S. Application Data
(60) Provisional application No. 60/204,436, filed on May 14, 2000.

(51) Int. Cl. C30B 7/00; C30B 21/02; C30B 28/06

(52) U.S. Cl. 117/68

(57) ABSTRACT

The present invention provides novel devices and method for kinetically controlling vapor diffusion in crystal growth. The devices comprise discrete diffusion pathways which control the kinetics of vapor diffusion between the crystal growth solution and the reservoir. The devices can comprise a channel which can be of varying lengths or geometries. The channel can either be static or controlled actively or dynamically. Alternatively, the diffusion pathways are provided by the material of the device itself. The device comprises porous and/or water absorbing materials through which the vapor can diffuse. The vapor diffusion rate can be controlled by the thickness or material of the device, or a combination of both.

### SPONSORSHIP

Work on this invention was supported in part by NASA Cooperative Agreement No. NCC8-126. The Government has certain rights in the invention.

### FIELD OF THE INVENTION

This invention relates generally to a method and device for growing crystals, and particularly to a method and device for controlling vapor diffusion rates during crystal growth.

### BACKGROUND OF THE INVENTION

Structural information for biological molecules has proven beneficial for understanding structure/function relationships and for applications such as structure-based drug design. X-ray crystallography is the predominant technique used to obtain three-dimensional structure information for biological molecules. A critical component of this technique is the growth of high-quality, well ordered crystals of the target molecule. Advances in X-ray diffraction equipment, data-collection methods and computational capabilities have progressed to the point where the growth of high-quality crystals is often the rate-limiting step for the determination of three-dimensional structures.

Many different techniques have been used in the attempt to grow high-quality crystals of biological molecules. The most widely used crystal growth technique, vapor-diffusion, utilizes a growth solution containing the biological molecule of interest and a precipitating agent. A popular vapor-diffusion configuration, typically described as the hanging-drop method, uses a reservoir solution containing precipitant and a buffered biological molecule/precipitation solution which ‘hangs’ from a sealed coverslip position over the reservoir. The initial solution conditions are such that water vapor diffuses from the crystal growth solution into the reservoir solution, thereby increasing the concentration of the biological molecule beyond its solubility point. One significant limitation of the traditional vapor-diffusion technique is that the evaporation of water from the growth solution (within a particular geometry) is fixed by the starting concentrations of the solution components. Thus, the rate at which the approach to supersaturation of the growth solution occurs is unchangeable by the experimenter, even if modification of this evaporation rate is desirable.

One method for dynamically controlling crystal growth and the rate of vapor diffusion is to control the concentrations of the precipitating agent during crystallization. U.S. Pat. No. 5,641,681 discloses an apparatus that comprises two chambers for containing reservoir solutions having different concentrations of precipitant. One of the chambers is in contact with the growth solution and the chambers are connected by a channel. Over time, the two reservoir solutions will equilibrate, changing the concentration of precipitate in each and thereby controlling vapor diffusion. Similar apparatus have been designed to control vapor diffusion and are disclosed in U.S. Pat. Nos. 4,886,646, 4,917,707, and 5,961,934. A significant drawback to these apparatus and methods is that the complicated apparatus involved limits the number of samples that can be run at any one time. The approach to finding suitable conditions that yield high quality protein crystals is a trial and error process, where more than 1,000 crystallization conditions are typically screened.

Thus it would be desirable to provide a simpler device and method to control vapor diffusion during crystal growth. It would be further desirable if the apparatus and method allow the screening of a large number of crystal growth conditions at the same time. It would also be desirable to have an apparatus that is inexpensive to manufacture.

### SUMMARY OF THE INVENTION

Novel devices and method for kinetically controlling vapor diffusion in crystal growth are provided. The devices compromise discrete diffusion pathways which control the kinetics of vapor diffusion between the crystal growth solution and the reservoir. In one embodiment, the device comprises a channel which can be of varying lengths or geometries. The channel can either be static or controlled actively or dynamically.

In a further embodiment, the device comprises more than one channel. The channels can have the same length and/or geometries or they can be different. In a preferred embodiment, the multiple channels allow the crystal growth solution to be selectively in contact with different reservoir solutions.

In an alternate embodiment, the diffusion pathways are provided by the material of the device itself. The device comprises porous and/or water absorbing materials through which the vapor can diffuse.

The devices and methods provided can be used with any configuration of the vapor diffusion technique for growing crystals. Preferably, the devices and methods are used in the hanging-drop or sitting drop methods. Additionally, the devices and methods provided herein can be used to grow crystals of biological materials, such as, but not limited to, proteins, peptides, viruses and nucleic acid molecules including fragments of biological materials and chemically modified biological materials.

Additional objects, advantages and features of the present invention will become apparent from the following description and appended claims, taken in conjunction with the accompanying drawings.

### BRIEF DESCRIPTION OF THE DRAWINGS

The various advantages of the present invention will become apparent to one skilled in the art by reading the following specification and subjoined claims and by referencing the following drawings in which:

FIG. 1 is a graph showing the relationship between the diameter of the channel and the amount of water evaporated over time;

FIG. 2A is a schematic illustrating hanging-drop vapor-diffusion crystal growth using a device with two channels;

FIG. 2B is a schematic illustrating sitting-drop vapor-diffusion crystal growth using a device with two channels;

FIG. 2C is a schematic illustrating hanging-drop vapor-diffusion crystal growth using a device with two channels;

FIG. 3 is a schematic illustrating a vapor diffusion rate-controlling device being inserted into a well of a plate;

FIG. 4 is a schematic illustrating a vapor diffusion rate-controlling device inserted into a well of a plate;

FIG. 5 is a schematic illustrating a cross-sectional view of a vapor diffusion rate-controlling device inserted into a well of a plate;

FIG. 6 is a schematic illustrating the use of a vapor diffusion rate-controlling device in hanging-drop vapor-diffusion crystal growth;

FIG. 7 is a schematic illustrating the use of a vapor diffusion rate-controlling device in sitting-drop vapor-diffusion crystal growth;

FIG. 8A is a schematic showing a top view of a solid vapor diffusion rate-controlling device;

FIG. 8B is a schematic showing a cross-sectional view of a solid vapor diffusion rate-controlling device;

FIG. 9A is a schematic showing a top view of a solid vapor diffusion rate-controlling device;

FIG. 9B is a schematic showing a cross-sectional view of a solid vapor diffusion rate-controlling device;

FIG. 10 is a graph showing the relationship between the number of days for appearance of crystals and the diameter of the channel;

FIG. 11 is a graph showing the relationship between the number of crystals obtained and the diameter of the channel;

FIG. 12A is a photograph showing the crystals obtained in the control;

FIG. 12B is a photograph showing the crystals obtained using a device with a 1 mm channel;

FIG. 12C is a photograph showing the crystals obtained using a device with a 2 mm channel;

FIG. 12D is a photograph showing the crystals obtained using a device with a 3 mm channel;

FIG. 13 is a schematic showing a cross-sectional view of a vapor diffusion rate controlling device having an optically clear center section;

FIG. 14 is a schematic showing a cross-sectional view of a vapor diffusion rate controlling device having an optically clear window in the center;

FIG. 15 is a schematic showing a cross-sectional view of a vapor diffusion rate controlling device having an optically clear window in the center;

FIG. 16 is a schematic showing a top view of a solid vapor diffusion rate controlling device;

FIG. 17 is a schematic showing a view of a multi-part vapor diffusion rate controlling device; and

FIG. 18 is a schematic showing a view of a multipiece vapor diffusion rate controlling device having multiple channels and multiple reservoir solution chambers.

### DETAILED DESCRIPTION OF THE PREFERRED EMBODIMENTS

Novel devices and method for kinetically controlling vapor diffusion in crystal growth are provided. The devices comprise discrete diffusion pathways which control the kinetics of vapor diffusion between the crystal growth solution and the reservoir. In one embodiment, the device comprises a channel which can be of varying lengths and/or geometries. The channel can either be static or controlled actively or dynamically.

In a further embodiment, the device comprises more than one channel. The channels can have the same length and/or geometries or they can be different. In a preferred embodiment, the multiple channels allow the crystal growth solution to be selectively in vapor contact with different reservoir solutions.

In an alternate embodiment, the diffusion pathways are provided by the material of the device itself. The device comprises porous and/or water absorbing materials through which the vapor can diffuse.

In one embodiment, the device has one or more discrete channels which provide at least one diffusion pathway between the crystal growth solution and the reservoir solution. By ‘crystal growth solution’ it is meant any solution that contains the biological molecules to be crystallized. The biological molecules can be, but not limited to, proteins, peptides, viruses, or nucleic acid molecules including fragments of biological materials and chemically modified biological materials.

By reservoir solution it is meant any solution containing a precipitating agent. A precipitating agent, by way of non-limiting example, is a compound which affects crystal growth through controlling the solubility of biological molecules in the crystal growth solution. Salts, such as ammonium sulfate and sodium chloride, or polyethylene glycol are used as precipitating agents to control the solubility of biological molecules in the crystal growth solution. Such precipitating agents are well known in the art.

By “contact” or “vapor contact” it is meant that the vapor or gaseous phase of the solution is in contact with or interacts with the vapor or solution of at least one reservoir solution. Alternatively, the vapor or gaseous phase of the reservoir solution can be in contact or interact with the vapor or solution of the crystal growth solution.

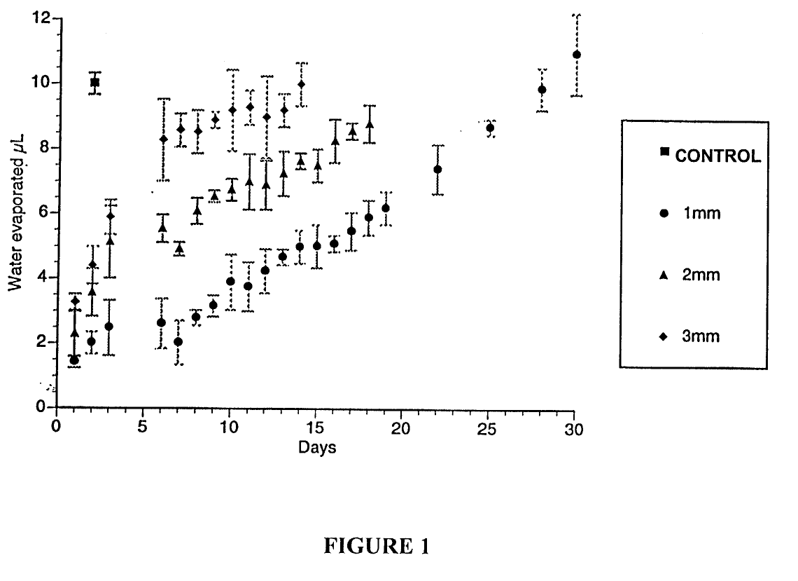

In a preferred embodiment, solvent vapor diffusion between the two solutions is controlled by the size (i.e. diameter and length) and/or geometry of the channel. While not wishing to be bound by theory, lengthening the channel or having a non-linear channel will increase the pathway that the solvent vapor molecules must travel, thereby slowing the rate of vapor diffusion. Non-limiting examples of non-linear geometries are channels with several right angles or channels that zig-zag or are curved. Alternatively, the vapor diffusion rate can be controlled by the diameter of the channel. The vapor diffusion rate is directly proportional to the channel diameter, decreasing as the channels become narrower. As shown in FIG. 1, the amount of water that has diffused is significantly lower with a channel with a 1 mm diameter (circles) as compared to channels with 2 mm (triangles) or 3 mm (diamonds) diameters. It will be appreciated by those skilled in the art that the size of the channel will depend on the container it is being placed into. For example, when the containers are the wells of a 24-well plate, such as, but not limited to, a LINBRO™ or COSTAR™ plate, it may be desirable to have a device with a channel diameter from about 0.5 mm to about 4 mm. If smaller containers (i.e. the wells of a 96-well plate) are used, then the diameter will be proportionately smaller. The size of the channel will also depend on the volume of the crystal growth and reservoir solutions. The smaller the volume of crystal growth solution, the more desirable it will be to have a smaller channel so that the diffusion rate is proportional to the smaller sample size.

In a further embodiment, the size and/or geometry of the channel is actively controlled. In a preferred embodiment, the geometry of the channel may be actively controlled. For example, a valve in a straight channel can be activated to close off lower portion of the channel and open the upper portion to a new channel to provide a zig-zag pathway. Alternatively, the device may comprise two or more channels having different diameters. The vapor diffusion rate can then be actively controlled by alternating between channels or between having one or both open. Furthermore, the channels can actively be closed by the user, thereby stopping further equilibration of the crystal growth solution with the reservoir solutions.

In an alternative embodiment, the device may further comprise at least one channel that is filled with a material porous to solvent vapor molecules. The porous material can be, but not limited to , agarose gel, polyacrylamide gel, gellen gum, aerogels, solution filled aerogels, GORE-TEX™ and zeolite. It will be appreciated that the density of the porous material will further affect solvent vapor diffusion rates.

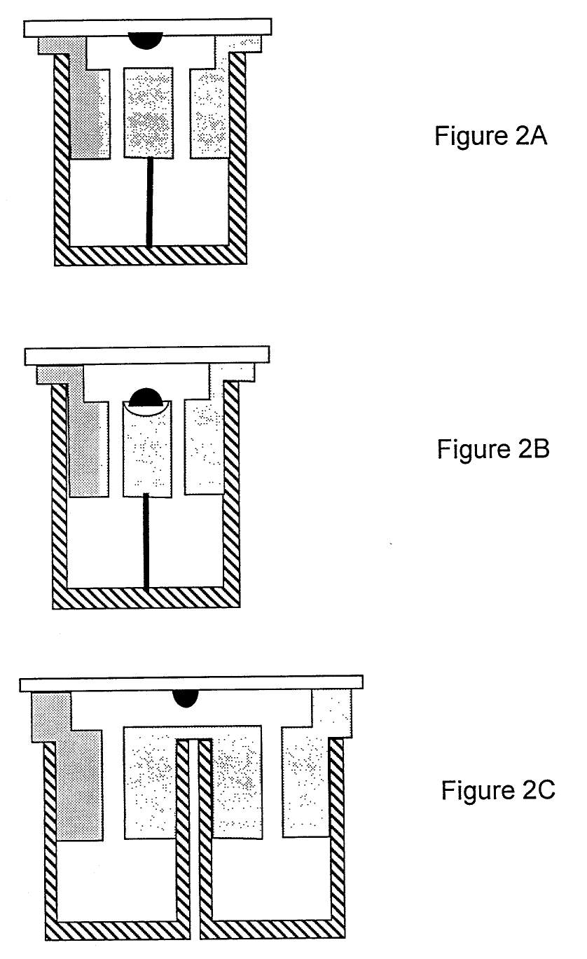

In yet another embodiment, the device comprises multiple channels, wherein each channel provides a pathway between a single crystal growth solution and multiple reservoir solutions (FIGS. 2A-C and 18). In a preferred embodiment, different reservoir solutions control different crystal growth parameters. For example, one reservoir may affect the volume of the crystal growth solution by drawing off or adding solvent by diffusion while a second reservoir contains a solution that affects the pH of the crystal growth solution. In a further embodiment, the multiple channels are selectable. The different reservoirs may contain different concentrations of precipitating agent and thus it would be desirable to have contact between the crystal growth solution and only a select number of channels at the same time, switching between channels at different times during crystal growth.

Device 110 of FIG. 18 is given by way of non-limiting example. The device has discrete channels 118 in unit 116. Channels 118 are connected to single channel 124 via channel 122 having opening 126 that allow vapor contact between the crystal growth solution and reservoir solution. Channels 118 align with reservoir chambers 114 of unit 112. Each channel 118 provides vapor contact between a desired reservoir solution in the reservoir chambers 114. Gates 120 of channels 118 control vapor contact between a reservoir solution and a drop of crystal growth solution. The gates can either be in the closed position 120a blocking vapor contact, fully open 120b to allow full vapor contact, or any position inbetween. Preferably the gates are actively controlled to give a range of vapor pathway dimensions. Either one, two or all three channels can be open simultaneously to control crystal growth. It will be appreciated that device 110 is for illustrative purposes and that the device may have any number of channels and reservoirs.

Units 116 is placed on top of unit 112 so that each of the channels is aligned with a reservoir chamber 114. Preferably the units are also sealed together so that vapor contact between the reservoir and the drop is only through the discrete channels 118. The device may be sealed using an o-ring as illustrated in FIG. 5 where unit 116 would fit into the reservoir unit 112. Cover 128 is then placed on unit 116 and sealed. Preferably the cover is made from an optically transparent rigid material. The device can be used for hanging drop vapor diffusion crystallization where drop 130 is placed on cover 128. Alternatively, the device can be used with sitting-drop vapor diffusion methods in which the drop sits in an indentation on the top of unit 116. Alternatively, the units may also be sealed together by placing the units and cover together in a sleeve or container that allows the units to be tightly sealed so that vapor communication is only through the discrete channels.

In a further embodiment, the multiple channels can be actively controlled. It may be desirable to have multiple channels between the crystal growth solution and two or more reservoir solutions with different concentrations of precipitating agents. The solvent vapor diffusion rate is then controlled by switching between various channels. In a preferred embodiment, control of the geometry of the channel or switching between channels is in response to sensors in the crystallization systems. Non-limiting examples of such sensors are static light scattering, dynamic light scattering, RAMAN spectroscopy, absorption spectroscopy, or video analysis.

In one embodiment, the device is made from materials that are non-porous or minimally porous to water and/or aqueous solvent vapors. Diffusion of the solvent vapors will thus be limited to the defined channels. Preferably, the device is made from teflon. In an alternate preferred embodiment, the device is made from an optically transparent material. Non-limiting examples of such materials are glass, ZEONEX™ and ZEONON™.

In another embodiment, the device comprises a solid portion that comprises an optically transparent material. The presence of the optically clear material allows for easier monitoring of crystal growth. The channel or channels can be placed either in the optically transparent material or in the other areas, or both. The solid, optically transparent portion can either be at the center of the device or offset from center. An example of a device having an optically transparent center portion is shown in FIG. 13. Device 40 has an outer ring 46 made of any material that is water impervious or is minimally pourous. This outer portion 46 has an o-ring 50 to help create a seal when the device is placed into a container. The device further comprises an optically clear portion 42 having channel 44. The top of the device has an indentation so there is room for a hanging drop on the cover 48.

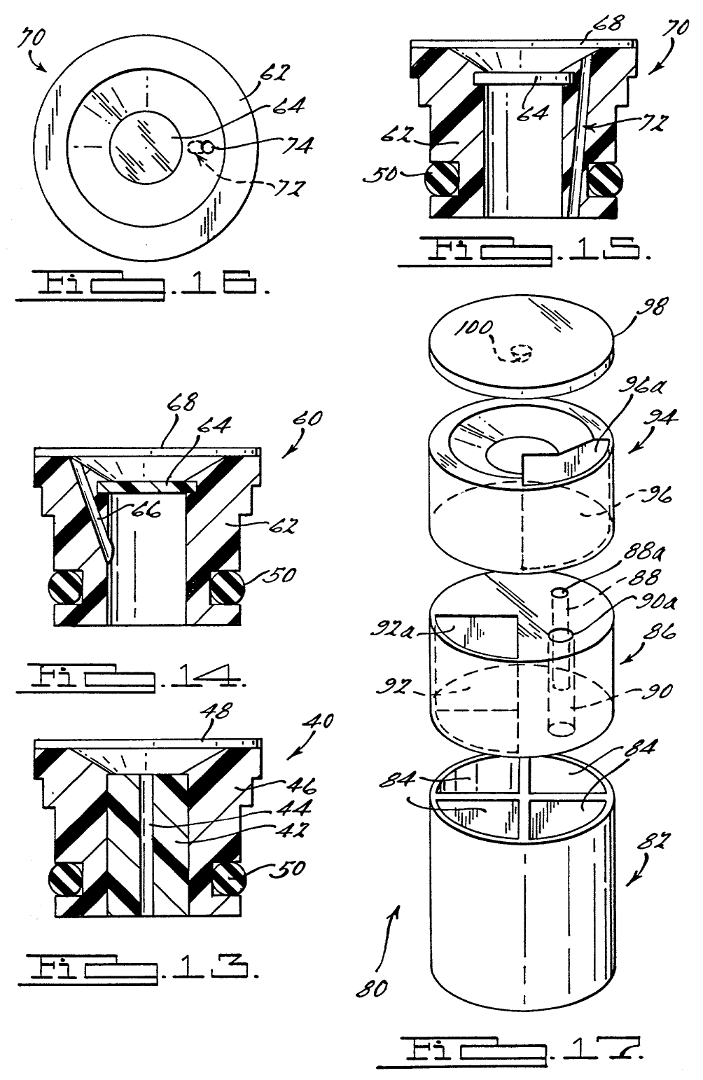

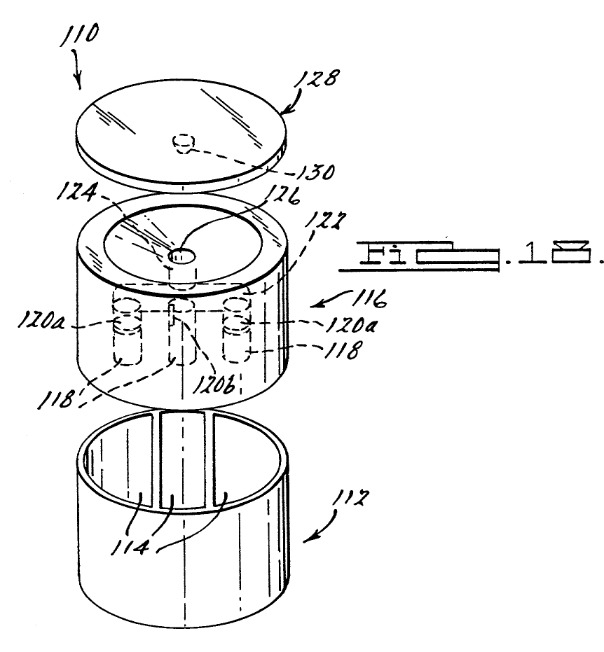

In an alternate embodiment, the device comprises an insert made of an optically transparent material. The insert can be placed in the center of the device and at least one channel is placed in the outer solid portion of the device. It will be appreciated by the skilled aritsan that as the proportional size of the window to the outer solid portion increases, there may be insufficient space for a channel with the desired diameter. Multiple channels with smaller diameters are then placed in the outer solid portion with a combined area for vapor diffusion similar to the larger channel. By way of non-limiting example, four 2 mm diameter channels can be placed in the outer solid portion in place of one 4 mm diameter channel. Likewise, two channels with 2 mm diameters and one channel with a 1 mm diameter can be placed to give the same area as a 3 mm diameter channel. There is an open space underneath the insert to aid in the monitoring of crystal formation. Alternatively, the insert can be offset and the channel is placed in the solid portion of the device. It will be appreciated that the channels will have the same embodiments as described for the device made of a single material. Non-limiting examples of the device are shown in FIGS. 14 and 15. In both device 60 and device 70, the insert 64 is set into solid portion 62 and tightly sealed. Channel 66 is placed in the solid portion 62 and goes from between the top of device 60 to a spot partially down the open portion of the device. Alternatively, channel 72 goes from the top of device 70 to the bottom. It will be appreciated by the skilled artisan that the geometry (i.e. length or diameter) of the channel can be altered to affect crystal growth. A top view of either device 60 or 70 is shown in FIG. 16. Insert 64 is set in the center of device 70 while opening 74 of channel 72 is shown offset from the center.

In a preferred embodiment, the insert is tightly sealed in the device such that there is no vapor communication between the reservoir and the drop of crystal growth solution except through a discrete channel or channels. In an alternate embodiment the optically transparent insert or solid portion is large enough to view the drop of crystallization solution. Those skilled in the art will determine the size limit of the optically transparent insert or solid portion based on the volume of the drop of crystal growth solution. It will be appreciated that the insert or solid portion can be larger than is necessary to optically monitor the drop of solution.

In another embodiment, the device is made to fit into a container holding the reservoir solution. The container can be any size or shape. Preferably, the container is circular. More preferably, the container is a well of a 24-well or 96-well plate. The device can be of a single diameter or cross-dimension along it's length or it can vary in dimensions along it's length to fit a number of containers varying in size. Preferably the cross dimension of the device is proportionately smaller at the bottom as compared to the top. In a more preferred embodiment, the device further comprises an o-ring around the part that fits into the container. The o-ring allows for a better seal between the device and the sides of the container as well as allows for minor variations in container sizes. In another preferred embodiment, the device has a collar of material sufficient to allow the device to rest in the proper position in the container. Although the collar is not required to use the device in the manner intended by the present invention, such a modification would be desirable to prevent the device from being placed into the container such that there was no space between the bottom of the channel and the reservoir solution.

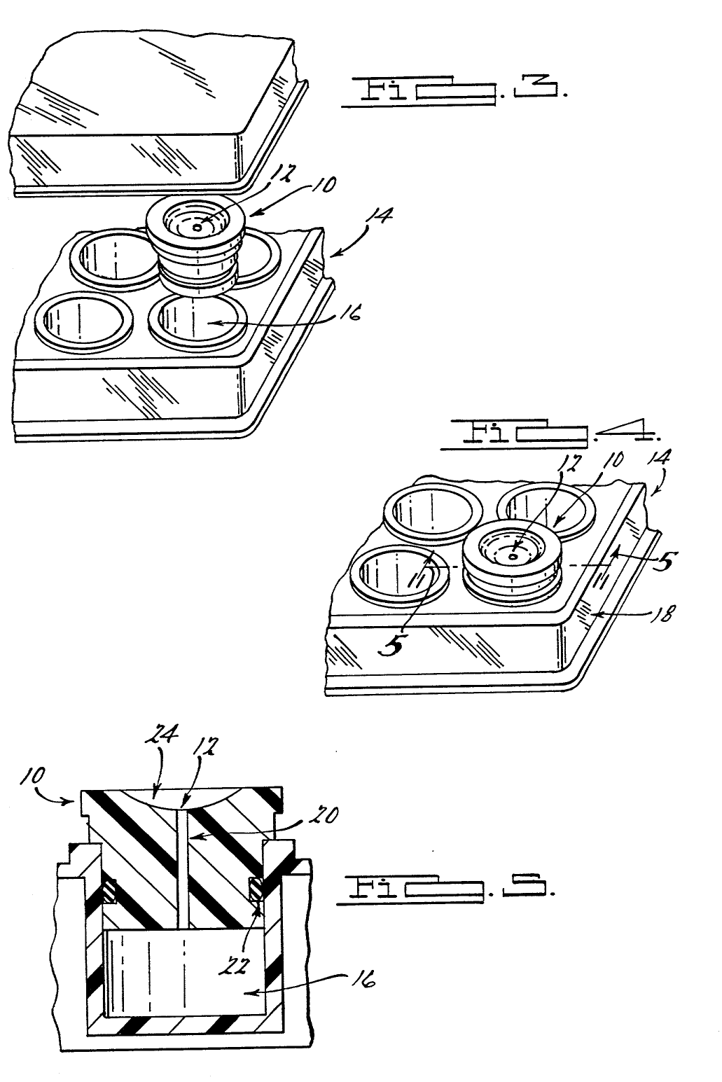

An example of a device made to fit a well of a 24-well plate is shown in FIGS. 3-5. The device 10 is set down into well 16 found on the plate 14, with collar 15 resting on the top of the container. The opening to the channel 12 is shown on the top of device 10. FIG. 4 shows the device 10 fully inserted into well 16. FIG. 5 is a cross-sectional view along axis 18 showing the device 10 inserted into well 16. Channel 20 provides access between the top of the device and the bottom of the well. An o-ring 22 helps to form a tight seal between device 10 and the walls of well 16.

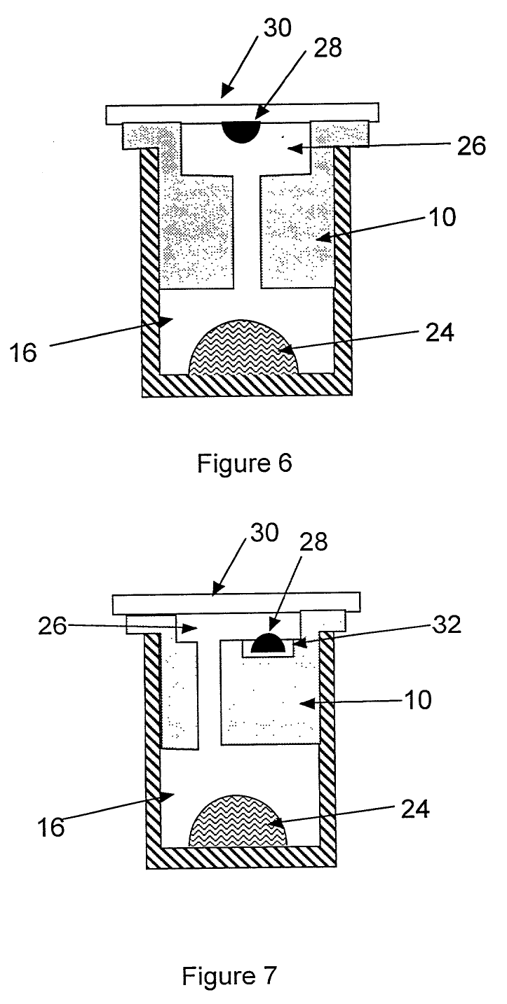

Methods for using the devices of the present invention in vapor-diffusion crystal growth are also provided. In one embodiment, the device is used in hanging-drop vapor-diffusion crystal growth. A precipitating solution 24 is placed in the bottom of the container 16 and device 10 is then inserted into the container (FIG. 6). The device 10 has a depression 26 in the top portion. The depression is deep enough for a drop 28 of a desired volume to hang down from a coverslip 30. A drop of crystal growth solution is placed on the coverslip 30 and the coverslip is placed on top of the device 10 with the drop hanging down. The coverslip 30 is then sealed to the top surface of the device 10. The coverslip is sealed to the device using acrylic tape, grease, wax or any other material with limited permeability to water that does not permanently join the coverslip to the device. Preferably the seal used will be optically clear to the method used to detect crystal growth. The entire system, e.g. container, device, solutions and cover slip, are kept at the desired temperature and crystal growth is monitored by methods known in the art.

In another embodiment, the device is used in sitting-drop vapor-diffusion crystal growth. A reservoir solution 24 is placed in the bottom of container 16 and device 10 is then inserted into the container (FIG. 7). For sitting-drop vapor-diffusion the device comprises a channel and a depression set into the top of the device. The depression holds a drop of crystal growth solution and the size of the depression will depend on the volume of the drop. For smaller devices, it may be necessary to position the channel to one side of the device (FIG. 7). A drop 28 is placed into depression 32 and the entire system sealed to the outside. The system is sealed by sealing a coverslip to the device using acrylic tape, grease, wax or any other material with limited permeability to water that does not permanently join the coverslip to the device. Alternatively, the system may be sealed by using tape alone. Preferably the seal used will be optically clear to the method used to detect crystal growth. The entire system, e.g. container, device, solutions and cover slip, are kept at the desired temperature and crystal growth is monitored by methods known in the art.

It will be appreciated that although FIGS. 6 and 7 show devices having one channel, the methods of the present invention can be used with devices having a multiplicity of channels.

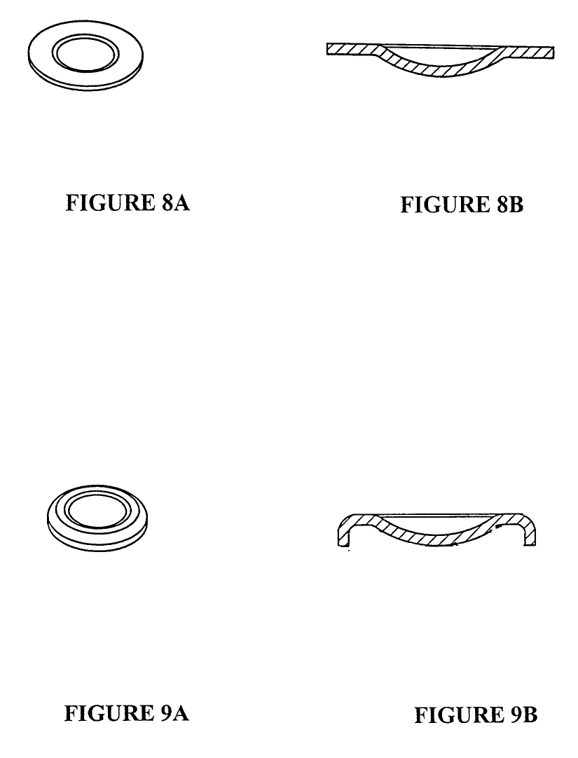

In one embodiment, the device is a solid piece made of at least one material porous to aqueous solvent vapor (FIGS. 8A and B, 9A and B). Such porous materials are well known to those in the art. Preferably, the porous material is polycarbonate or polystyrene. The device is shaped so that it fits on top of a container containing a reservoir solution. There should be a good seal between the device and the container so that the solution vapor is forced to diffuse through the device. Furthermore, when a cover is set on top of the device to seal it, there should be adequate room for a drop of crystal growth solution of a desired volume.

The discrete diffusion pathways of the device are an integral part of the porous materials of the device. In a preferred embodiment, the vapor diffusion rate is controlled by the choice of material. The water absorption and permeability properties of the porous material will control the vapor diffusion rate. For example, the greater the absorption and permeability, the greater the vapor diffusion rate. Such properties of porous materials are published in various handbooks and are known to those skilled in the art. In an alternate preferred embodiment the vapor diffusion rate is controlled by the thickness of the device. If a slower rate is desired, the thickness of the device is increased. Conversely, if a faster rate is desired, the thickness of the device is decreased. The vapor diffusion rate can be further controlled by varying both the materials and thickness of the device.

In another embodiment, the vapor diffusion rate can be actively or dynamically controlled by using a material whose density or orientation will change upon being exposed to an electric or magnetic field. A change in density or orientation will then affect the vapor diffusion rate. In a preferred embodiment, the exposure to an electric or magnetic field is in response to sensors in the crystallization systems. Non-limiting examples of such sensors are static light scattering, dynamic light scattering, RAMAN spectroscopy, absorption spectroscopy, or video analysis.

Methods are also provided for using the solid devices in hanging- and sitting-drop vapor-diffusion crystal growth. A precipitating solution is placed within a container and the device is placed on top of the container so that a seal is formed between the device and the edges of the open end of the container. A drop having a desired volume is either placed on a coverslip (hanging drop) or in a depression on the device (sitting drop) and then a coverslip is then set on top of the device. The coverslip is sealed to the device and the entire system, e.g. container, device, solutions and cover slip, are kept at the desired temperature and crystal growth is monitored by methods known in the art.

In one embodiment, the device of the present invention can comprise multiple units that interact with each other to provide different combinations of channel geometries with different reservoir solutions. For example, one unit is a reservoir unit or well having at least one reservoir chamber. In a preferred embodiment the reservoir unit has more than one reservoir chamber. The number of chambers will depend on the number of reservoir required for crystal growth. The second unit comprises multiple channels having different geometries and configurations. A third unit comprises an open channel that allows vapor contact between a drop or drops of crystal growth solution and reservoir solutions via the channels of the second unit. In a preferred embodiment, device 80 has a reservoir unit 82, a channel unit 86 and a selection unit 94 (FIG. 17). Reservoir unit 82 is divided into four equal chambers 84 to allow for different reservoir solutions. Channel unit 86 has channels to match up with at least one of the reservoir chambers 84. By way of non-limiting example, channel unit 86 has two discrete channels, smaller channel 88 and larger channel 90. Channel unit 86 also has open area 92 as well as an area that has no opening to the reservoir unit. Channel unit 86 fits onto reservoir unit 82 in such a manner as to allow rotation of the channel unit 86 to match different channels and with different reservoirs, thereby controlling crystal formation in the drop of crystal growth solution. Selection unit 94 controls which channel and reservoir solution has vapor contact with the drop of crystal growth solution. Selection unit 94 has opening 96 providing vapor contact between a reservoir solution and crystal growth solution. In a preferred embodiment, opening 96 is large enough that it does not kinetically control vapor contact. Selection unit 94 is placed onto channel unit 86 in such a manner that it can be rotated to select the desired channel and reservoir conditions. Cover 98 is placed on top of unit 94 having a hanging drop of crystal growth solution 100. It will be appreciated that the device of the present invention may also be used with a sitting drop. If a sitting drop is used, an indentation for holding the drop may be made in unit 94.

The three units of the device fit together in such a manner that each unit may be rotated. Preferably the units are also sealed together so that vapor communication between the reservoir and the drop is only through the discrete channels or openings.

In operation, channel unit 86 is rotated to align the desired channel with the appropriate reservoir chamber 84 containing the appropriate reservoir solution to produce the desired crystal growth conditions. Selection unit 94 is then rotated so opening 96 is aligned with the desired channel, allowing vapor contact to occur between the crystal growth solution and the reservoir solution. cover 98 having drop 100 of crystal growth solution is placed on selection unit 94 and all units and cover are sealed together. When new crystal growth conditions are desired, channel unit 86 is rotated to align a new channel with desired reservoir chamber 84. Alternatively, the same channel can be used but rotated to a reservoir chamber 84 having a different reservoir solution than the one initially used. Finally, selection unit 94 is rotated to align opening 96 with the new channel. Preferably cover 98 remains sealed to selection unit 94 when changing the channel and/or reservoir.

In a further embodiment, the units of the device can be manually rotated or can be actively controlled. In a preferred embodiment, control of the units is in response to sensors in the crystallization systems. Non-limiting examples of such sensors are static light scattering, dynamic light scattering, RAMAN spectroscopy, absorption spectroscopy, or video analysis.

The device of the present invention has the advantage that it allows for rehydration of the crystal growth solution. To rehydrate the drop, open area 92 of channel unit 86 is aligned with a reservoir containing a rehydrating solution. Unit 94 is then aligned with open area 92 to expose the drop of crystallization solution to the rehydrating solution. Rehydrating the solution during crystallization can control the crystal population and optimize crystal growth.

The forgoing and other aspects of the invention may be better understood in connection with the following example, which is presented for purposes of illustration and not by way of limitation.

### EXAMPLE

### Results

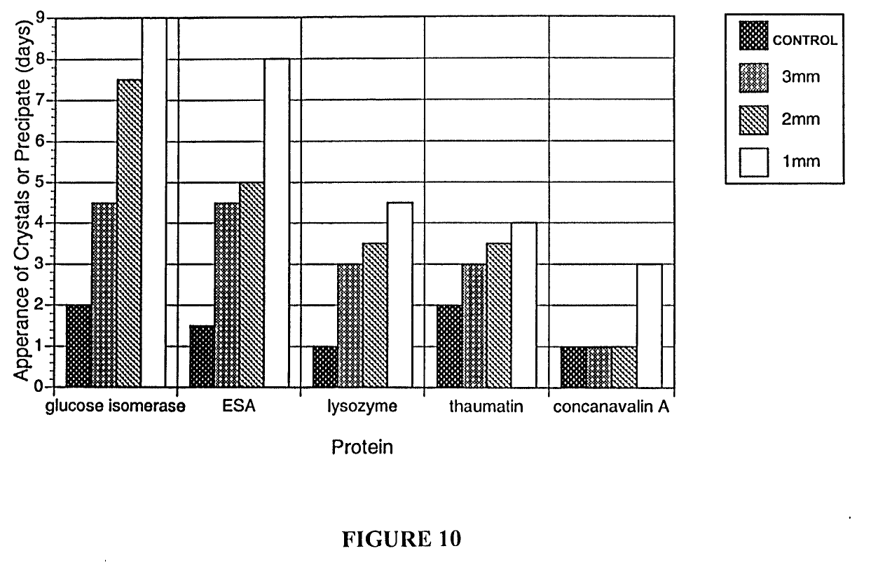

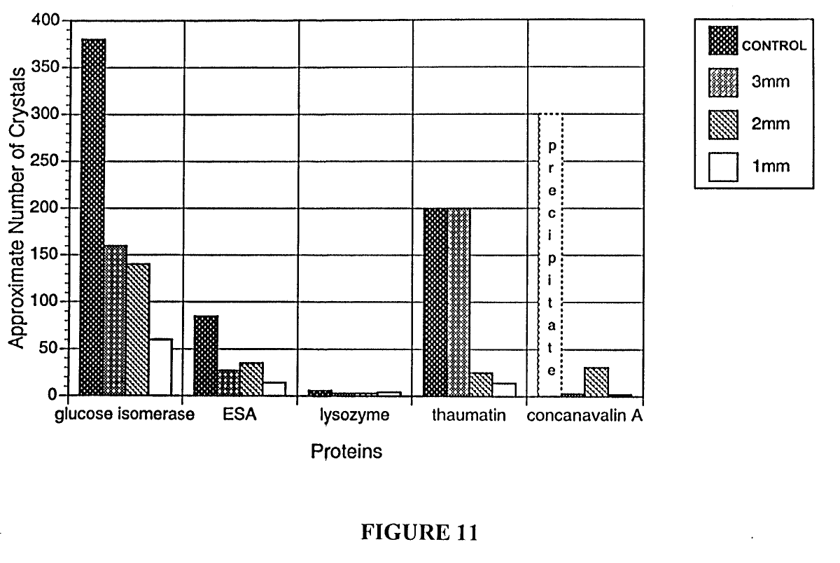

Five different proteins, glucose isomerase, equine serum albumin (ESA) lysozyme, thaumatin and concanavalin A were crystallized using either no device, or devices with 1 mm, 2 mm or 3 mm diameter channels. The devices affected both the rate that crystals appeared and the number of crystals that formed for all five proteins. The number of days required until either crystals or precipitate was observed was dependant on the size of the channel (FIG. 10). Crystals appeared within 1-2 days in the control samples whereas crystals didn't appear until 2-5 days with the 3 mm channel, 2-7 days with the 2 mm channel and 3-9 days with the 1 mm channel. The number of crystals formed after 14 to 24 days was affected in a similar manner with the largest population of crystals formed in the control experiments and successively smaller populations of crystals for 3 mm, 2 mm, and 1 mm channels, respectively (FIG. 11). The largest amount of crystals were obtained in the controls with the exception of concanavalin A, where only a precipitate was observed. The relationship between the size of the channel and the number of crystals varied from protein to protein (FIG. 11). For example with ESA and concanavalin A, the 2 mm channel produced more crystals than either the 1 mm or 3 mm channel.

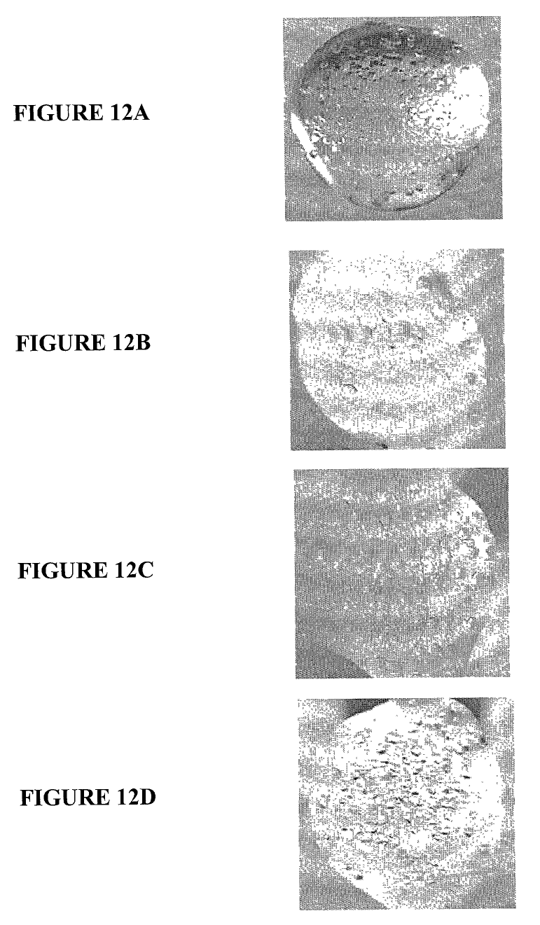

The visual quality of the crystals were also affected. As shown in FIGS. 12A-D, the crystals obtained with the devices were larger and more easily separated than those of the control. Typically, larger and more defect-free crystals are obtained if the crystal growth rate is minimized.

### Methods

Glucose Isomerase: The protein stock solution contained 45 mg/mL of glucose isomerase in 10 mM Pipes buffer (pH 7.2) and 10 mM magnesium chloride. The reservoir solution was 1.2 M ammonium sulfate in 10 mM Pipes buffer (pH 7.2). The crystal growth solution was formed by mixing equal volumes of the protein solution with the reservoir solution to give a final solution having 22.5 mg/mL protein and 0.6 M ammonium sulfate in 10 mM Pipes buffer (pH 7.2).

Equine Serum Albumin: The protein stock solution contained 50 mg/mL of ESA in 50 mM acetate buffer (pH 5.6). The reservoir solution contained 50% saturated ammonium sulfate in 50 mM acetate buffer (pH 5.6). The crystal growth solution was formed by mixing equal volumes of the protein solution with the reservoir solution to give a final solution having 25 mg/mL of protein and 25% saturated ammonium sulfate in 50 mM acetate buffer (pH 5.6).

Concanavalin A: The protein stock solution contained 16 mg/mL of protein in 50 mM phosphate buffer (pH 7.4). The reservoir solution contained 2.8 M ammonium sulfate in 50 mM phosphate buffer (pH 7.4). The crystal growth solution was formed by mixing equal volumes of the protein solution with the reservoir solution to give a final solution having 8 mg/mL of protein and 1.4 M ammonium sulfate in 50 mM phosphate buffer (pH 7.4).

Lysozyme: The protein stock solution contained 40 mg/mL of protein in 50 mM acetate buffer (pH 4.7). The reservoir solution contained 7% NaCI in 50 mM acetate buffer (pH 4.7). The crystal growth solution was formed by mixing equal volumes of the protein solution with the reservoir solution to give a final solution having 20 mg/mL protein and 3.5% NaCI in 50 mM acetate buffer (pH 4.7).

Thaumatin: The protein stock solution contained 68 mg/mL protein in N-[2-acetamido]-2-iminodiacetic acid (ADA) (pH 6.5). The reservoir solution contained 1.0 M sodium potassium tartrate in ADA (pH 6.5). The crystal growth solution was formed by mixing equal volumes of the protein solution with the reservoir solution to give a final solution having 34 mg/mL protein and 0.5 M sodium potassium tartrate in ADA (pH 6.5).

The foregoing discussion discloses and describes merely exemplary embodiments of the present invention. One skilled in the art will readily recognize from such discussion, and from the accompanying drawings and claims, that various changes, modifications and variations can be made therein without departing from the spirit and scope of the invention as defined in the following claims.

All patents and other publications cited herein are expressly incorporated by reference.

I claim:

1. A device for kinetically controlling the rate of vapor diffusion during crystal growth comprising discrete diffusion pathways, wherein said pathways affect the vapor diffusion rate between a crystal growth solution and a reservoir solution.

2. The device of claim 1 wherein the diffusion pathways of the device are discrete channels.

3. The device of claim 2 wherein the device comprises at least two channels, wherein the channels are between the crystal growth solution and at least two different reservoir solutions.

4. The device of claim 2 wherein channel size or geometry can be actively controlled.

5. The device of claim 1 wherein the device is made of a material porous to a vapor moving between the crystal growth solution and the reservoir solution.

6. A method of controlling the rate of vapor diffusion between a crystal growth solution and a reservoir solution comprising the device of claim 1.

7. A method for crystallization of a biological molecule comprising the steps of:
(a) placing a reservoir solution in the bottom of a container;
(b) placing a device comprising discrete diffusion pathways in the top of the container;
(c) placing a crystal growth solution on the opposite end of the device from the reservoir solution; and
(d) sealing the container, the device and the solutions.

8. The method of claim 7 wherein the crystal growth solution is placed in a well on the device.

9. The method of claim 7 wherein the crystal growth solution is placed on a coverslip, wherein the crystal growth solution is hanging over the device.

10. The method of claim 7 wherein the device comprises at least one channel between the crystal growth solution and the reservoir solution.

11. The method of claim 10 wherein the device comprises at least two channels.

12. The method of claim 11 wherein each of the channels are between the crystal growth solution and at least two different reservoir solutions.

13. The method of claim 7 wherein the device comprise a material porous to vapor from the solutions.

14. A device for kinetically controlling the rate of vapor diffusion during crystal growth comprising:
(a) a reservoir unit comprising at least one reservoir chamber;
(b) a channel unit comprising at least one discrete channel; and
(c) a selection unit comprising an opening wherein the opening is large enough not to control the rate of vapor diffusion;
wherein the reservoir unit, the channel unit and the selection unit can rotate to align the reservoir chamber, the discrete channel and the opening.

15. The device of claim 14 further comprising a cover.

16. The device of claim 14 wherein the channel unit further comprises an opening wherein the opening is large enough not to control the rate of vapor diffusion.

17. The device of claim 14 wherein the channel unit is sealed onto the reservoir unit and the selection unit is sealed onto the channel unit.

18. The device of claim 14 wherein at least one channel of the channel unit is actively controlled.
